(19) United States
(12) Patent Application Publication
(10) Pub. No.: US 2012/0064364 A1
(43) Pub. Date: Mar. 15, 2012

(54) COATED ARTICLE

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHUN-MAO LIN, Shenzhen (CN)

(73) Assignees: HON HAI PRECISION INDUSTRY CO., LTD., TU-CHENG (TW); HONG FU JIN PRECISION INDUSTRY (SHENZHEN) CO., LTD., SHENZHEN CITY (CN)

(21) Appl. No.: 13/084,642

(22) Filed: Apr. 12, 2011

(30) Foreign Application Priority Data
Sep. 9, 2010 (CN) 201010277218.3

(51) Int. Cl. B32B 15/01; C23C 14/34; C23C 14/14

(52) U.S. Cl. 428/635; 204/192.15

(57) ABSTRACT

A coated article includes a substrate, and a coating deposited on the substrate that comprises an equal number of alternating densification layers and corrosion resistance layers. The densification layers are made of tin or aluminum; the corrosion resistance layers are made of chromium, niobium, vanadium, zirconium, titanium, or manganese.

### BACKGROUND

1. Technical Field

The exemplary disclosure generally relates to coated articles and a method for manufacturing the coated articles.

2. Description of Related Art

Physical vapor deposition (PVD) has conventionally been used to form a coating on metal bases of cutting tools or molds. Materials used as this coating material are required to have excellent corrosion resistance. At present, chromium, niobium and titanium are mainly used as a material satisfying these requirements. However, these coating materials have a plurality of micropores. Environmental air and vapor can pass through the micropores to corrode the metal bases.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 is a cross-section of an exemplary embodiment of an article.

FIG. 2 is a schematic view of a magnetron sputtering coating machine for manufacturing the coated article in FIG. 1.

### DETAILED DESCRIPTION

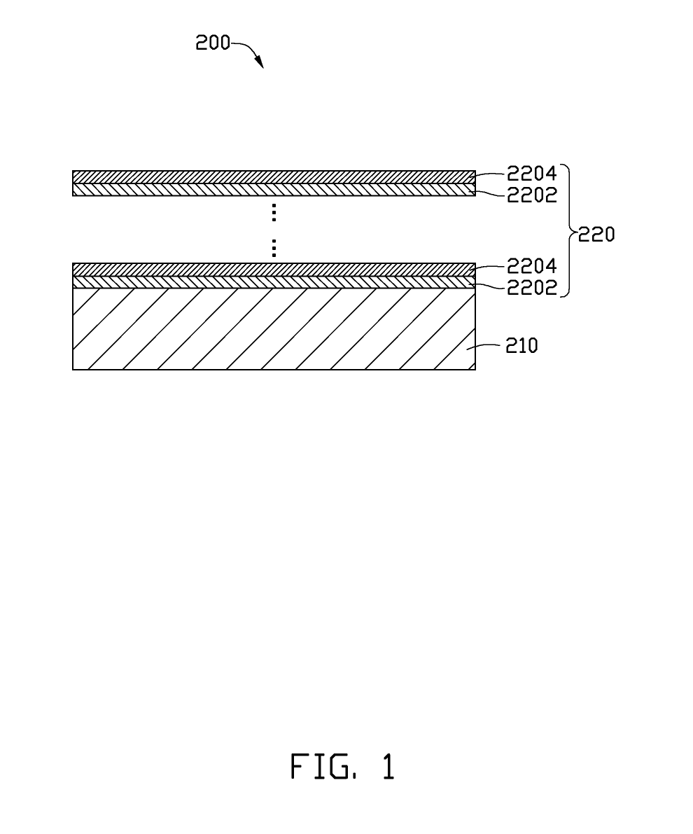

Referring to FIG. 1, a coated article 200 includes a substrate 210 and a coating 220 deposited on the substrate 210. The coating 220 includes an equal number of alternating densification layers 2202 and corrosion resistance layers 2204. The number of the densification layers 2202 is between 2 and 4, and the number of the corrosion resistance layers 2204 is also between 2 and 4. The substrate 210 may be made of aluminum, aluminum alloy, magnesium, or magnesium alloy. The densification layers 2202 may be made of a metal having a low melting point such as tin or aluminum. The corrosion resistance layers 2204 may be made of metal having high melting point such as chromium, niobium, vanadium, zirconium, titanium, or manganese. Each densification layer 2202 has a thickness between about 0.1 micrometers and about 1.0 micrometer. Each corrosion resistance layer 2204 has a thickness between about 0.1 micrometers and about 1.0 micrometer. The densification layers 2202 and the corrosion resistance layers 2204 may be deposited by magnetron sputtering. The coating 220 bonds/contacts with the substrate 210 by a corrosion resistance layer 2204 or a densification layer 2202.

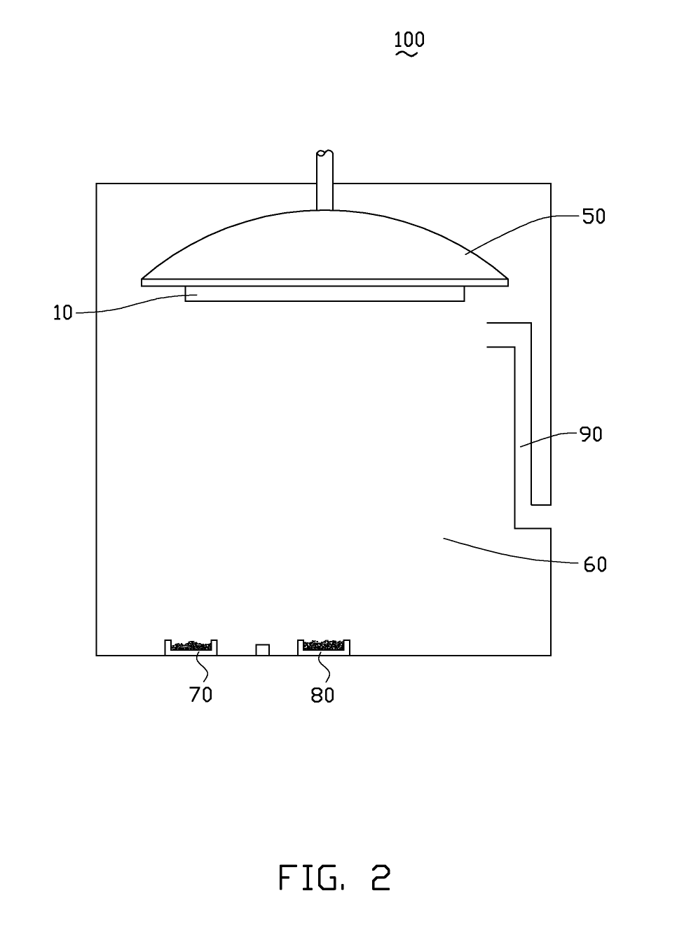

Referring to FIG. 2, a method for manufacturing the coated article 200 may include at least the following steps.

Providing a substrate 210. The substrate 210 may be made of aluminum, aluminum alloy, magnesium, or magnesium alloy.

Pretreating the substrate 210, by washing it with a solution (e.g., Alcohol or Acetone) which can be done in an ultrasonic cleaner, to remove impurities, such as grease, or dirt. The substrate 210 is dried. The substrate 210 is then cleaned by argon plasma cleaning.

Providing a vacuum sputtering coating machine 100. The vacuum sputtering coating machine 100 includes a sputtering coating chamber 20 and a vacuum pump 30 connecting to the sputtering coating chamber 20. The vacuum pump 30 is used to pump the air out the sputtering coating chamber 20. The vacuum sputtering coating machine 100 further includes a rotating bracket 21, two first targets 22, two second targets 23 and a plurality of gas inlets 24. The rotating bracket 21 rotates the substrate 210 in the sputtering coating chamber 20 relative to the first targets 22 and the second targets 23. The first targets 22 face each other, and are respectively located at opposite sides of the rotating bracket 21. The second targets 23 face each other, and are respectively located at opposite sides of the rotating bracket 21. In this exemplary embodiment, the first targets 22 are tin targets or aluminum targets, the second targets 23 are chromium targets, niobium targets, vanadium targets, zirconium targets, titanium targets, or manganese targets.

A coating 220 is deposited on the substrate 210. The temperature in the sputtering coating chamber 20 is set between about 25 degrees Celsius (° C.) and about 200° C. Argon is floated into the sputtering coating chamber 20 at a flux between about 100 Standard Cubic Centimeters per Minute (sccm) and about 500 sccm from the gas inlets 24. The first targets 22 and the second targets 30 in the sputtering coating chamber 20 are alternatively evaporated to deposit an equal number of alternating densification layers 2202 and corrosion resistances layer 2204 on the substrate 210. Each densification layer 2202 has a thickness between about 0.1 micrometers and about 1.0 micrometer. Each corrosion resistance layer 2204 has a thickness between about 0.1 micrometers and about 1.0 micrometer. The densification layers 2202 have a good compactness that can improve the corrosion resistance of the coating 220 to prevent the coated article 200 from corroding by environmental air or vapor.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

1. A coated article, comprising:
a substrate;
a coating deposited on the substrate, the coating comprising an equal number of alternating densification layers and corrosion resistance layers, wherein
each densification layer is tin or aluminum; each of the corrosion resistance layers is niobium, vanadium, zirconium, titanium or manganese.

2. The coated article as claimed in claim 1, wherein there are between 2 and 4 densification layers.

3. (canceled)

4. The coated article as claimed in claim 1, wherein the substrate is made of aluminum, aluminum alloy, magnesium or magnesium alloy.

5. The coated article as claimed in claim 1, wherein each densification layer has a thickness between about 0.1 micrometers and about 1.0 micrometer.

6. The coated article as claimed in claim 1, wherein each corrosion resistance layer has a thickness between about 0.1 micrometers and about 1.0 micrometer.

7. The coated article as claimed in claim 1, wherein each of the densification layers is deposited by magnetron sputtering.

8.-9. (canceled)

10. A coated article, comprising:
a substrate;
a coating deposited on the substrate, the coating comprising an equal number of alternating densification layers and corrosion resistance layers, wherein
each densification layer is tin; each of the corrosion resistance layers is niobium, vanadium, zirconium, titanium or manganese.

11. The coated article as claimed in claim 10, wherein there are between 2 and 4 densification layers .

12. The coated article as claimed in claim 10, wherein the substrate is made of aluminum, aluminum alloy, magnesium or magnesium alloy.

13. The coated article as claimed in claim 10, wherein each densification layer has a thickness between about 0.1 micrometers and about 1.0 micrometer.

14. The coated article as claimed in claim 10, wherein each corrosion resistance layer has a thickness between about 0.1 micrometers and about 1.0 micrometer.

15. The coated article as claimed in claim 10, wherein each of the densification layers is deposited by magnetron sputtering.
